(19) United States
(12) Patent Application Publication
(10) Pub. No.: US 2026/0271311 A1
(43) Pub. Date: Sep. 10, 2026

(54) Multi-layer electrode connection structure, on-chip capacitor, and a multi-layer electrode connection method

(71) Applicant: JIASHAN FUDAN RESEARCH INSTITUTE, Jiaxing (CN)

(72) Inventors: Wenlong XU, Jiaxing (CN); Bao ZHU, Jiaxing (CN); Shijin DING, Jiaxing (CN); Bocheng ZHANG, Jiaxing (CN); Lilong ZHANG, Jiaxing (CN); Nianwen YU, Jiaxing (CN); Wei ZHANG, Jiaxing (CN)

(73) Assignee: JIASHAN FUDAN RESEARCH INSTITUTE, Jiaxing (CN)

(21) Appl. No.: 19/362,439

(22) Filed: Oct. 19, 2025

(30) Foreign Application Priority Data
Mar. 6, 2025 (CN) 202510258824.7

(51) Int. Cl. H10D 1/68; C23F 17/00

(52) U.S. Cl. CPC H10D 1/696; H10D 1/714; H10D 1/716; C23F 17/00

(57) ABSTRACT

The present invention relates to the technical field of semiconductor, and aims to provide a multi-layer electrode connection structure, an on-chip capacitor and a multi-layer electrode connection method, applied on an on-chip capacitor, the structure comprising: a substrate, for providing a surface for attaching an electrode layer on a lowermost layer; electrode layers having at least one etched trench, for providing at least one first region and at least one second region which are conductive; profiles of neighboring etched trenches in N layers of electrode layers do not intersect along a stacking direction, N is an integer greater than two; and at least one dielectric layer, located in between adjacent electrode layers for provided dielectrics for insulation. The structure aims to reduce breakdown of the multi-layer electrodes and promise performance of the capacitor.

### CROSS-REFERENCE

This application claims the benefit of priority from China Patent Application No. CN 202510258824.7 filed on Mar. 6 2025, the contents of which are hereby incorporated by reference in their entirety.

### TECHNICAL FIELD

The present invention relates to the technical field of semiconductors, especially a multi-layer electrode connection structure, on-chip capacitor and multi-layer electrode connection method.

### BACKGROUND TECHNOLOGY

For silicon based capacitors, usually dielectric materials and electrode materials are deposited on silicon wafers to form a multi-layer structure to increase capacitance values. With the increase of the number of layers, displaced connection of layers of electrodes becomes increasingly difficult, especially on a nanometer scale. In the products which are commercially available at present, it is necessary to etch a fixed depth after forming a multi-layer structure of alternating electrode and dielectric layers in order to lead out both the positive and negative electrodes to separate the positive and negative electrode sheets, and processing difficulties and cost increase along with the increase of the number of layers. Where there are a large number of layers, positions etched for leading out the electrode will collapse and a gap will appear. The gap will not only influence subsequent deposition of dielectric layers and electrode layers, additional electric field unevenness will be introduced in between the electrode layers, strength of local electric field may be too high, leakage current will be increased, insulation performance of dielectric layers will be reduced, in worse cases dielectric breakdown may occur, which will influence the performance of the capacitor. Therefore, a multi-layer electrode connection structure, an on-chip capacitor and a multi-layer electrode connection method is required to improve the foregoing conditions.

### SUMMARY OF INVENTION

The present invention aims to provide a multi-layer electrode connection structure, an on-chip capacitor and a multi-layer electrode connection method, and the structure aims to reduce breakdown of the multi-layer electrodes and promise performance of the capacitor.

On one aspect, the present invention provides a multi-layer electrode connection structure, applied on an on-chip capacitor, the structure comprising: a substrate, for providing a surface for attaching an electrode layer on a lowermost layer; electrode layers having at least one etched trench, for providing at least one first region and at least one second region which are conductive; profiles of neighboring etched trenches in N layers of electrode layers do not intersect along a stacking direction, N is an integer greater than two; and at least one dielectric layer, located in between adjacent electrode layers for provided dielectrics for insulation.

Optionally, a number of the electrode layers is M, M is greater than or equal to N; where M equals N, the profiles of the etched trenches in the N layers of the electrode layers are not intersecting along the stacking direction.

Optionally, where M is greater than N, the profiles of the etched trenches in the N layers of the electrode layers and the profiles of the etched trenches of the electrode layers more than N layers intersect in part.

Optionally, the electrode layers has at least one first edge and at least one second edge which are opposite, the etched trenches in the adjacent electrode layers are respectively close to the at least one first edge and the at least one second edge so to have the at least one first region and the at least one second region in the adjacent electrode layers stacked alternately.

Optionally, at least one trench is provided in the substrate; and a width of the at least one trench is greater than a width of the etched trenches.

Optionally, the at least one trench is distributed on a surface of the substrate in a similar patterned array; and a shape of the at least one trench comprises any of strips, rectangle and circle.

On a second aspect, the present invention provides an on-chip capacitor, comprising: the multi-layer electrode connection structure as set forth in any paragraph of the first aspect, and a first conductive end cap, for connecting the at least one first region in the electrode layers; at least one second conductive end cap, for connecting the at least one second region in the electrode layers; and the at least one first conductive end cap and the at least one second conductive end cap are isolated.

On a third aspect, the present invention provides a multi-layer electrode connection method, for forming the multi-layer electrode connection structure as set forth in any paragraph describing the first aspect, wherein the method comprising: S1, providing a substrate, forming electrode layers on a surface of the substrate; S2, etching the electrode layer on a surface layer, and divide the electrode layer to be at least one first region and at least one second region by at least one etched trench; S3, forming at least one dielectric layer on a surface of the electrode layer; forming another electrode layer on an upper surface of the at least one dielectric layer; S4, repeating steps S2-S3, executing S2 again; wherein profiles of the etched trenches in adjacent electrode layers among the N layers of electrode layers are not intersecting along a stacking direction, and N is a positive integer greater than 2.

Optionally, the step S4 further comprises: cutting or grinding edges of stacked electrode layers so to expose the at least one first region and the at least one second region of the electrode layers.

Optionally, the method further comprising S5, forming at least one first conductive end cap for connecting the at least one first region and forming at least one second conductive end cap for connecting the at least one second region.

Optionally, the electrode layers and the at least one dielectric layer are formed by at least one of atomic layer deposition or chemical vapor deposition; wherein the at least one first conductive end cap and the at least one second conductive end cap are formed by electroplating.

Beneficial effects of the present invention are: by configuring the profiles of the adjacent etching trenches in the N electrode layers not to intersect along a stacking direction, formation of gaps due to accumulation of heights of the etched trenches in the N electrode layers is avoided, actual effective capacitance area is increased, the electric fields in the electrode layers are maintained uniform, too high local electric field strength is avoided, leakage current is reduced, insulation performance of the dielectric layer is improved, breakdown is prevented and performance of the capacitor can be improved.

### BRIEF DESCRIPTION OF DRAWINGS

FIG. 1 is a schematic diagram showing a multi-layer electrode connection structure according to the present invention;

FIG. 2 is a schematic structural diagram showing a substrate having at least one trench according to the present invention;

FIG. 3 is a schematic diagram showing a plurality of rectangular trenches on the substrate in a rectangular array according to the present invention;

FIG. 4 is a schematic diagram showing a plurality of strip-shaped trenches on the substrate in a linear array according to the present invention;

FIG. 5 is a schematic structural diagram showing an on-chip capacitor according to the present invention;

FIG. 6 is a flowchart schematic diagram showing a multi-layer electrode connection method;

FIG. 7 is a schematic structural diagram showing forming an odd number first electrode layer formed on the substrate according to the present invention;

FIG. 8 is a schematic structural diagram showing an odd number first electrode layer etching trench formed on the odd number first electrode layer according to the present invention;

FIG. 9 is a schematic structural diagram showing a first dielectric layer formed on the odd number first electrode layer according to the present invention;

FIG. 10 is a schematic structural diagram showing an odd number second electrode layer formed on the first dielectric layer according to the present invention;

FIG. 11 is a schematic structural diagram showing the odd number second electrode layer etched trench formed on the odd number second electrode layer according to the present invention; and

FIG. 12 is a schematic structural diagram showing a second dielectric layer formed on the odd number second electrode layer according to the present invention.

Numerical marks in the drawings are:
1 substrate; 5 conductive end cap;
11 trench; 21 odd number first electrode layer; 22 even number first electrode layer; 31 odd number second electrode layer; 32 even number second electrode layer; 41 first dielectric layer; 42 second dielectric layer; 43 third dielectric layer; 51 first conductive end cap; 52 second conductive end cap;
201 odd number first electrode layer etched trench; 202 even number first electrode layer etched trench; 211 odd number first electrode layer positive electrode region; 212 odd number first electrode layer negative electrode region; 221 even number first electrode layer positive electrode region; 222 even number first electrode layer negative region;
301 odd number second electrode layer etched trench; 302 even number second electrode layer etched trench; 311 odd number second electrode positive electrode region; 312 odd number second electrode negative electrode region; 321 even number second electrode positive electrode region; and 322 even number second electrode layer negative electrode region.

### EMBODIMENTS

In order to make the purpose, technical solutions and advantages of the present invention clearer, the technical solutions in the embodiments of the present invention will be clearly and completely described below in conjunction with the drawings of the present invention. Obviously, the described embodiments are part of the embodiments of the present invention, not all of the embodiments. Based on the embodiments of the present invention, all other embodiments obtained by those of ordinary skill in the art without making creative work are within the scope of protection of the present invention. Unless otherwise defined, the technical terms or scientific terms used herein should be the common meanings understood by those of ordinary skill in the art to which the present invention belongs. The terms “comprising” and similar terms used in the present description mean that the elements or objects appearing before the terms cover the elements or objects listed after the terms and their equivalents, without excluding other elements or objects.

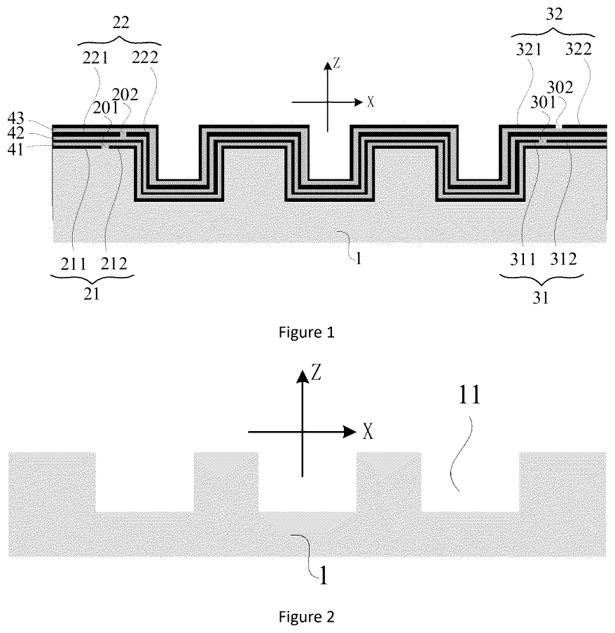

In view of the problems existing in the art, as shown in FIG. 1, a first embodiment of the present invention provides a multi-layer electrode connection structure, for use in an on-chip capacitor, the structure comprising: a substrate 1, for providing a surface for attaching an electrode layer at a bottom layer on; electrode layers having at least one etched trench, for providing a first region and a second region which are conductive; profiles of adjacent etched trenches in the N electrode layers are not intersecting along a stacking direction, N is a positive integer greater than two; and at least one dielectric layer, located in adjacent electrode layers, for providing insulation dielectrics. In the present invention, by configuring the profiles of the adjacent etched trenches in the N electrode layers not to intersect along the stacking direction, formation of a gap due to accumulation of differences in heights of the etched trenches in the electrode layers is avoided, an actual effective capacitance area can be improved, an electric field in the electrode layers can be maintained uniform, too high local electric field strength can be avoided, leakage current can be reduced, insulation performance of the dielectric layers can be enhanced, and performance of the capacitor can be improved.

In other specific embodiments, the stacking direction of the N electrode layers is along a vertical direction Z, and an extension direction of the substrate 1, the electrode layers and the dielectric layers is along a horizontal direction. The etched trenches are configured to be inserted in the electrode layers along the vertical direction Z until in contact with the substrate 1 or the dielectric layer.

In other specific embodiments, the substrate 1 is made from silicon, silicon oxide, zirconium oxide, hafnium oxide, germanium, silicon nitride, aluminum oxide, or gallium oxide. The electrode layers are configured to be conductive materials. The dielectric layers are configured to be insulation materials. The dielectric layers are further configured to fill the etched trenches on electrode layers thereunder so as to isolate the first region and the second region using the insulation materials.

In some embodiments, a number of the electrode layers is configured to be M, M is greater than or equal to N; where M equals N, profiles of the etched trenches in the N electrode layers do not intersect along the stacking direction.

In some specific embodiments, M=N=4, an odd number electrode layer 21 is connected on a surface of the substrate 1. The odd number first electrode layer 21 is connected with a first dielectric layer 41. An odd number second electrode layer 31 is connected with the first dielectric layer 41. A second dielectric layer 42 is connected with the odd number second electrode layer 31. An even number first electrode layer 22 is connected with the second dielectric layer 42. A third dielectric layer 43 is connected with the even number first electrode layer 22. An even number second electrode layer 32 is connected with the third dielectric layer 43. In the present embodiment, by configuring the etched trenches in the N electrode layers not to intersect, accumulation of differences of heights of the etched trenches is avoided, and a gap can be eliminated. Effective capacitance area of the capacitor can be improved, the electric field in the electrode layers can be maintained uniform, too high local electric field can be avoided, leakage currents can be reduced, insulation performance of the dielectric layers can be improved, breakdown can be prevented and performance of the capacitor can be improved.

In some examples, an odd number first electrode layer etched trench 201 along an inverse X direction is provided in the odd number first electrode layer 21, and an even number first electrode layer etched trench 202 along the inverse X direction is provided in the even number first electrode layer. The odd number first electrode layer etched trench 201 and the even number first electrode layer etched trench 202 are neighboring etched trenches, and profiles thereof do not intersect along a Z direction.

In other examples, an odd number second electrode layer etched trench 301 along an X direction is provided in the odd number second electrode layer 31, and an even number second electrode layer etched trench 302 along the X direction is provided in the even number second electrode layer 32. The odd number second electrode layer etched trench 301 and the even number second electrode layer etched trench 302 are neighboring etched trenches, and profiles thereof along the Z direction do not intersect.

It shall be set forth that, definitions of the etched trenches in the neighboring electrode layer are given according to micro-displacement fine trench patterning. In this way, sub-micrometer or even nanometer positioning precision can be achieved and integration levels of the integrated circuits can be improved.

In some embodiments, where M is greater than N, profiles of the etched trenches in the N electrode layers and the etched trenches in the electrode layers beyond N layers intersect in part.

In some specific embodiments, M=20, N=20, twenty layers of electrodes layers and twenty layers of dielectric layers are stacked on the substrate 1 along the Z direction, and a profile of the etched trench in the first layer electrode layer intersects with a profile of the etched trench in the 401th layer electrode layer along the Z direction; a profile of the etched trench in the 2^{nd} layer electrode layer intersects with a profile of the etched trench in the 402th layer electrode layer along the Z direction; and a profile of the etched trench in the 10^{th} layer electrode layer intersects with a profile of the etched trench in the 20^{th} layer electrode layer along the Z direction. In the present embodiment, by using repeatedly positions of the etched trenches at an interval of N layers, accumulation of the height differences of the etched trenches locally can be avoided as much as possible, the multi-layer electrode connection structure can reach more layers to satisfy the design of on-chip capacitors. On another aspect, in the present embodiment, by increasing the number of electrode layers to M layers, the effective surface area of the electrodes can be further increased and the capacitance density can be improved.

In some embodiments, the electrode layers have opposition first edges and second edges, the etched trenches in adjacent electrode layers are respectively close to the first edges and the second edges, so that the first regions and the second regions in the adjacent electrode layers can be alternately stacked.

In some specific embodiments, the first edges are located along the inverse X direction and the second edges are along the X direction. In some examples, the odd number first electrode layer negative electrode region 212, the odd number second electrode layer positive electrode region 311, the even number first electrode layer negative electrode region 222 and the even number second electrode layer positive electrode region 321 are alternately stacked together. In other specific embodiments, the first edges are along the X direction and the second edges are along the inverse X direction. In the present embodiment, by configuring the etched trenches in the electrode layers to be close to respectively the first edges and the second edges, space can be used more effectively, effective electrode area can be further increased and the capacitance density can be improved.

As shown in FIG. 2, in some embodiments, a trench 11 is provided in the substrate 1; a width of the trench 11 is greater than a width of the etched trenches. In some specific embodiments, the trench 11 is formed in a surface of the substrate by etching. In some examples, reactive ion etching processes are used to etch the silicon substrate, and a range of depth-width of the trench 11 is 1:100-100:1. A range of a width of the trench 11 is 0.5-100 μm. In other examples, a depth-width ratio of the trench 11 is 1:1. And a width of the trench 11 is configured to be 50.25 μm.

In the present embodiment, by controlling a size of the trench 11, electric signal paths can be optimized, and signal distortion can be reduced. In some examples, a cross section of the trench 11 perpendicular to the Y direction is configured to be rectangular. In other examples, a cross section of the trench 11 perpendicular to the Y direction is configured to be a trapezoid. In some other embodiments, the cross section of the trench 11 perpendicular to the Y direction is configured to be arc-shaped. A curved edge of the arc-shape can be provided to be a parabola, an ellipse, or a hyperbola. The horizontal X direction, the horizontal Y direction and the vertical Z direction are perpendicular to each other.

In some embodiments, the trenches 11 are distributed on a surface of the substrate 1 in a self-similar pattern array; and shapes of the trenches comprise at least one of strip-shape, rectangle or circle.

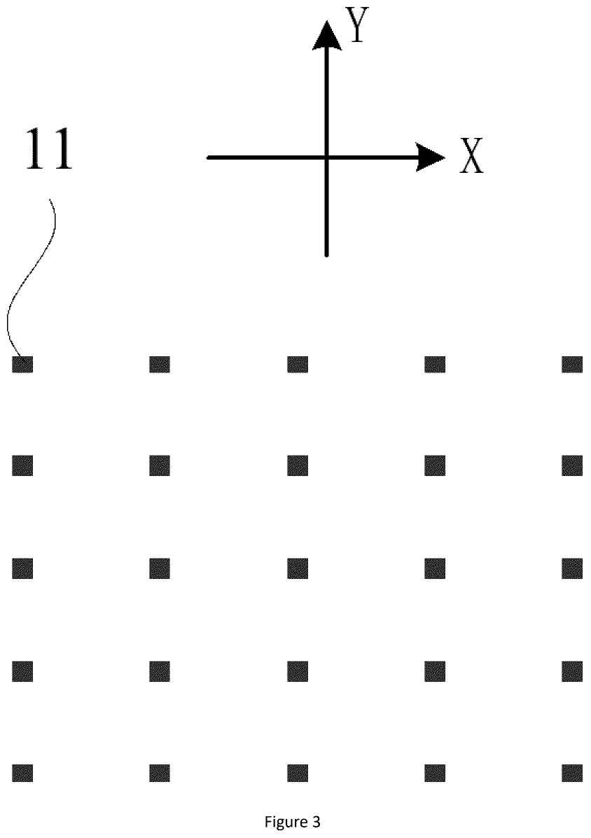

As shown in FIG. 3, in some specific embodiments, one of the trenches 11 is configured to be rectangular, some of the trenches 11 are arranged in a rectangular array, and an outer profile of the rectangular array is similar to the one of the trenches which is rectangular.

As shown in FIG. 4, in some other embodiments, one of the trenches is configured to be strip-shaped, and some of the trenches 11 are configured in a linear array. In some examples, an extension direction of the one of the trenches 11 is along the Y direction, and the linear array direction is along the X direction. In some other examples, both the extension direction of the one of the trenches 11 and the linear array direction are along the Y direction.

In the present embodiment, by configuring the trenches 11 on the surface of the substrate 1 in the self-similar pattern array the electric fields in between the electrode layers are distributed uniformly and can be designed in a large scale.

It shall be noted that, the etched trenches extend to edges of the electrode layers along the Y direction and an inverse Y direction. The trenches 11 are not required to extend to edges of the substrate 1.

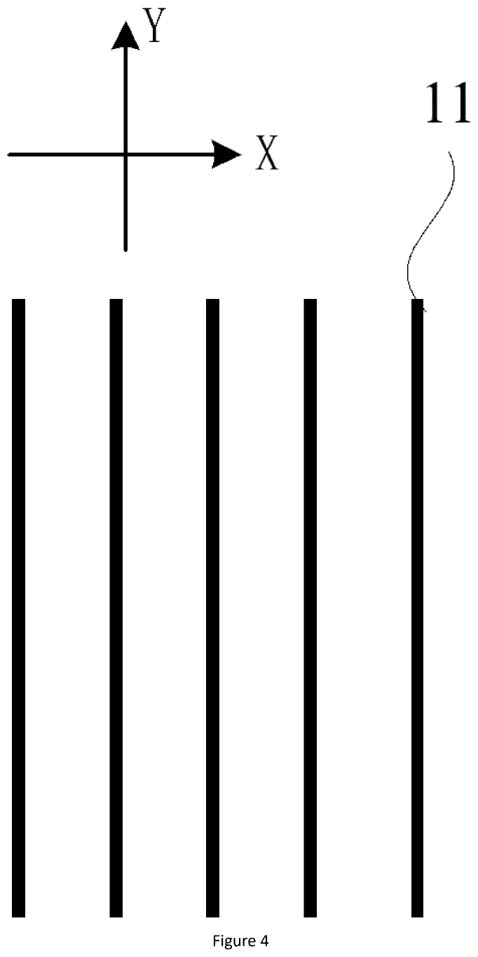

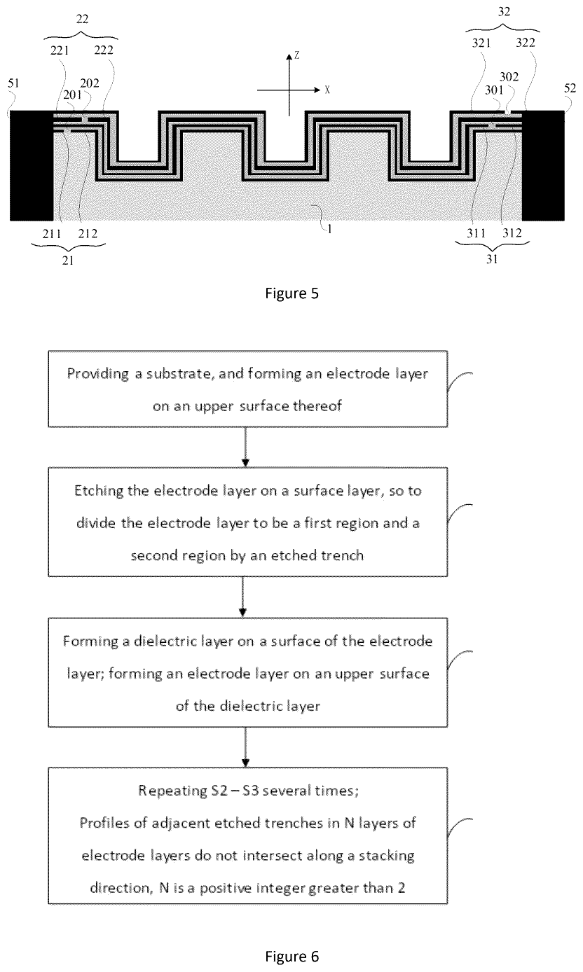

As shown in FIG. 5, the second embodiment provides an on-chip capacitor, comprising: the multi-layer electrode connection structure as set forth in the foregoing paragraphs, and a first conductive end cap 51, for connecting the first regions in the electrode layers; a second conductive end cap 52, for connecting the second regions in the electrode layers; and the first conductive end cap 51 and the second conductive end cap 52 are isolated.

In some embodiments, the first conductive end cap 51 is configured to connect a positive electrode, and the second conductive end cap 52 is configured to connect a negative electrode. Where an electric potential difference exists in between the positive electrode and the negative electrode, an electric field is formed in between the first region and the second region. In some other specific embodiments, the first conductive end cap 51 is configured to be connected with the negative electrode, the second conductive end cap 52 is configured to be connected with the positive electrode. It shall be noted that, by providing the first conductive end cap 51 and the second conductive end cap 52 to be isolated to connect neighboring electrode layers, the capacity of the capacitor can be improved.

In some examples, a number of the electrode layers is an even number, and electric charges are stored by alternating insulation layers and electrode layers. In other embodiments, a number of the electrode layers is an odd number, and the electrode layer at the top layer is not connected with the first conductive end cap 51 and the second conductive end cap 52 so as to be isolated. With this design, electromagnetic interference between the capacitor and other components can be reduced, especially in high frequency applications. Isolation of the electrode layer at the top layer can help to maintain the stable performance of the capacitor, and reduce electromagnetic interference to the external environment.

A third embodiment of the present invention provides a multi-layer electrode connection method, configured to form the multi-layer electrode connection structure as set forth in any of the foregoing paragraphs, comprising: S1, providing a substrate 1, forming an electrode layer thereon; S2, etching the electrode layer on the surface, so as to divide the electrode layer to be a first region and a second region by an etched trench; S3, forming a dielectric layer on the surface of the electrode layer; forming an electrode layer on an upper surface of the dielectric layer; S4, repeating steps S2-S3 for several times, executing S2 again; profiles of the adjacent etched trenches in the N electrode layers do not intersect, and N is a positive integer greater than 2.

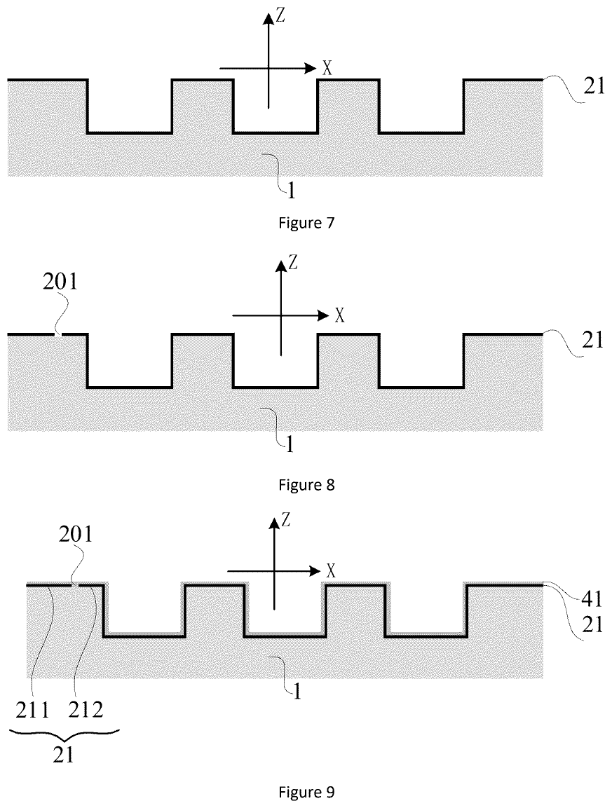

As shown in FIG. 7, in some specific embodiments, S1 further comprises: providing another substrate 1 having a trench 11 on an upper surface thereof, and the electrode layer is covered uniformly over an inner surface of the trench 11 and a surface of the original substrate 1 outside the trench 11. The surface of the original substrate 1 is connected with the side surface of the trench 11, which protrudes out of the bottom surface of the trench 11.

In some embodiments, the etched trench is provided in the surface of the original substrate outside the trenches 11. In other embodiments, the etched trenches are provided in the trenches 11, and an etching direction of the etched trenches is along a vertical Z direction. In other embodiments, the etched trenches are provided in the trenches 11, and the etching direction of the etched trenches are along the horizontal X direction or the inverse X direction.

It shall be noted that, the electrode layers and the dielectric layers are formed by at least one of atomic layer deposition or chemical vapor deposition. In the present embodiment, by repeated execution of the steps S2 and S3, a new layer is deposited on the former electrode layer and dielectric layer, and layer by layer accumulation of the multi-layer electrode structures is realized. In this process, high repeatability and control precision is exhibited, and large scale industrialized production of complex multi-layer structures is supported.

In a first example, pattern etching is done to the silicon substrate 1 having a dimension of 1 cm*1 cm by reactive ion-etching, a trench of a width of 50 μm and a depth of 40 μm is formed. S1 comprises: depositing 20 nm TiN on the surface of the silicon wafer using the atomic layer deposition process to serve as the odd number first electrode layer 21.

As shown in FIG. 8, first execution of the step S2 further comprises: S31: etching the odd number first electrode layer 21 at the first edges along the inverse X direction, forming an odd number first electrode layer etched trench 201, and dividing the odd number first electrode layer 21 to be odd number first electrode layer positive electrode 211 and odd number first electrode layer negative electrode 212.

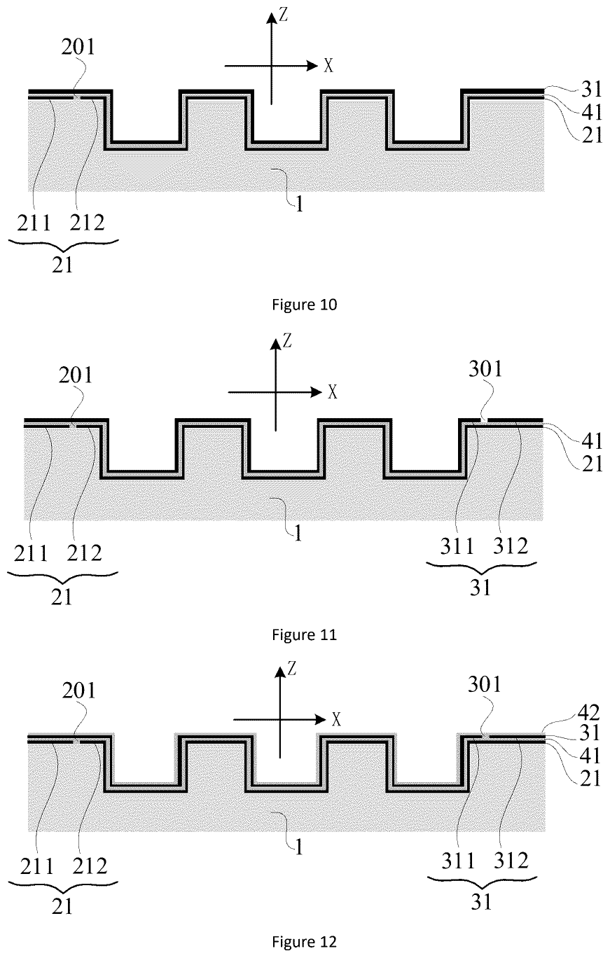

As shown in FIG. 9, first execution of the step S3 further comprises: S31: depositing zirconia or hafnium oxide 50 nm on a surface of the odd number first electrode layer 21 as the first dielectric layer 41 using atomic layer deposition. As shown in FIG. 10, depositing titanium nitride 50 nm on the first dielectric layer 41 as the odd number second electrode layer 31 using the atomic layer deposition process.

As shown in FIG. 11, second execution of S2 further comprises: S41: etching the odd number second electrode layer 31 at the second edges along the X direction, and forming the odd number second electrode layer etched trenches 301, viding the odd number second electrode layer 31 to be an odd number second electrode layer positive electrode region 311 and an odd number second electrode negative electrode region 312.

As shown in FIG. 12, second execution of S3 further comprises: S42, depositing zirconia or hafnium oxide 10 nm on a surface of the odd number second electrode layer 31 using chemical vapor deposition processes as a second dielectric layer 42. Depositing titanium nitride 20 nm on the second dielectric layer 42 as an even number first electrode layer 22.

Third execution of step S2 further comprises: S43, etching the even number first electrode layer 22 at the first edge along the X direction, forming an even number first electrode layer etched trench 202, and dividing the even number first electrode layer 22 to be an even number first electrode positive electrode region 221 and an even number first electrode negative electrode region 222.

Third execution of step S3 further comprises: S44, depositing zirconia or hafnium oxide 50 nm on a surface of the even number first electrode layer using the atomic layer deposition process. Depositing titanium nitride 50 nm on the third dielectric layer 43 using the atomic layer depositing process as the even number second electrode layer 32.

Fourth execution of S2 further comprises: S45, etching the even number second electrode layer 32 at the second edge along the X direction, forming the even number second electrode layer etched trench 302, and dividing the even number second electrode layer 32 to be an even number second electrode layer positive electrode region 321 and an even number second electrode layer negative electrode region 322.

Fourth execution of S3 further comprises: S46, depositing zirconia or hafnium oxide 50 nm on a surface of the even number second electrode layer 32 using chemical vapor deposition processes as the fourth dielectric layer.

Using the fourth dielectric layer as the substrate 1, repeating the steps S1-S46 for ten times, and forming the silicon based multi-layer electrode connection structure in the first example. In the present example, by combing the chemical layer deposition and chemical vapor deposition, thickness and quality of the dielectric layer (zirconia or hafnium oxide) can be controlled precisely, high dielectric coefficient materials can be used effectively, and energy density and efficiency of the capacitor can be improved. By selecting titanium nitride as the electrodes, with the excellent conductivity and thermal stability of titanium nitride, in combination with high dielectric coefficient materials, capacitance performance and thermal stability of the appliances is significantly improved, which meets the need for high performance electronic apparatuses.

In the second example, conducting pattern etching on the silicon substrate 1 cm*1 cm using the reactive ion-etching process, and forming a trench 11 having a width of 60 μm and a depth of 80 μm. Depositing metal tungsten 200 nm on the silicon wafer using the atomic layer deposition technology as the odd number first electrode layer 21.

As shown in FIG. 8, first execution of S2 further comprises: etching the odd number first electrode layer 21 at the first edge along the inverse X direction, forming the odd number first electrode layer etched trench 201, and dividing the odd number first electrode layer 21 to be an odd number first electrode layer positive electrode region 211 and an odd number first electrode negative electrode region 212.

As shown in FIG. 9, first execution of S3 further comprises: S31, depositing silicon oxide 20 nm on the surface of the odd number first electrode layer 21 using the chemical vapor deposition technology as the first dielectric layer 41. As shown in FIG. 10, depositing tungsten 300 nm on the first dielectric layer 41 to serve as the odd number second electrode layer 31.

As shown in FIG. 11, second execution of S2 further comprises: S41, etching the odd number second electrode layer 31 at the second edge along the X direction, forming the odd number second electrode layer etched trench 301, and dividing the odd number second electrode layer 31 to be an odd number second electrode layer positive electrode layer 311 and an odd number second electrode layer negative electrode region 312.

As shown in FIG. 12, second execution of S3 further comprises: S42, depositing silicon oxide 100 nm on a surface of the odd number second electrode layer 31 using the chemical vapor deposition technology. Depositing tungsten 200 nm on the second dielectric layer 42 as the even number first electrode layer 22.

Third execution of the step S2 further comprises: S43, etching the even number first electrode layer 22 at the first edge along the X direction, forming the even number first electrode layer etched trench 202, and dividing the even number first electrode layer 22 to be an even number first electrode layer positive electrode region 221 and an even number first electrode layer negative electrode region 222.

Third execution of S3 further comprises: S44, depositing silicon oxide 20 nm on a surface of the even number first electrode layer 22 at the first edge along the X direction as the third dielectric layer 43. Depositing titanium nitride 300 nm on the third dielectric layer 43 using chemical vapor deposition technology as the even number second electrode layer 32.

Fourth execution of S2 further comprises: S45, etching the even number second electrode layer 32 at the second edge along the X direction, forming the even number second electrode layer etched trench 302, and dividing the even number second electrode layer 32 to be an even number second electrode positive electrode layer 321 and an even number second electrode negative electrode region 322.

Fourth execution of S3 further comprising: S46, depositing zirconia or hafnium oxide 100 nm on a surface of the even number second electrode layer 32 using chemical vapor deposition processes as the third dielectric layer.

Using the fourth dielectric layer as the substrate 1, repeating execution of the steps S1-S46 for 15 times, and forming the silicon based multi-layer electrode connection structure as shown in the second example. Compared with other metals and alloys, tungsten has higher conductivity and better corrosion resistance, which not only increases the conductivity of the electrodes, but can improve the overall stability and service life of the appliances. By depositing silicon oxide 20 nm using the chemical vapor deposition technology as the first dielectric layer 41 in the step S3 at the very beginning, and changing the thicknesses of the subsequent dielectric layers (for example, silicon oxide 100 nm of the second dielectric layer 42), different dielectric materials and different thicknesses thereof can be adjusted, capacitance performance and leakage currents can be optimized so as to have a higher energy density or lower current leakage.

In some embodiments, S4 further comprises: cutting or grinding edges of the electrode layers to expose the first regions and the second regions of the electrode layers.

In some specific embodiments, first of all, cutting edges of the stacked electrode layers, grinding edges thereof, so that smooth sections of the first edges of the first regions of the electrode layers along a side of the inverse X direction are exposed, in the meanwhile, a smooth section is exposed at the second edges of the second regions of the electrode layers along a side of the X direction. In the present embodiment, by cutting and subsequent grinding of edges of the stacked electrode layers, smooth sections of the first edges and the second edges are shown along the side of the inverse X direction and the side of the X direction. In this way, edge smoothness of the electrode structure is improved, electric field concentration or short circuit due to rough edges can be reduced and reliability and electric performance of the apparatuses can be enhanced.

In some embodiments, the method further comprises S5, forming a first conductive end cap 51 for connecting the first regions of the electrode layers and a second conductive end cap 52 for connecting the second region of the electrode layers.

In some embodiments, the first conductive end cap 51 and the second conductive end cap 52 are formed by electroplating graphite paste. In the present embodiment, the conductive end caps 5 formed by electroplating using graphite paste can enhance significantly conductivity of electric connection between the electrode layers, promise effective current transmission, reduce resistance and losses, which is key to improve the overall electric properties. Graphite has good electric conductivity and stability, the end caps formed can counteract the influence of the environment on the electric connection and increase long-term stability and durability of the appliances. By depositing and forming the conductive end caps by electroplating, the thickness and uniformity of the deposited layers can be controlled precisely, which is suitable for large-scale manufacturing, manufacturing flow processes of the conductive end caps can be simplified and production efficiency can be improved and expenses reduced.

While the embodiments of the present invention have been described in detail above, it will be apparent to those skilled in the art that various modifications and variations of these embodiments are possible. However, it should be understood that such modifications and variations are within the scope and spirit of the present invention as set forth in the claims. Furthermore, the invention described herein can have other embodiments and may be practiced or implemented in a variety of ways.

1. A multi-layer electrode connection structure, applied on an on-chip capacitor, the structure comprising:
a substrate, for providing a surface for attaching an electrode layer on a lowermost layer;
N electrode layers having at least one etched trench, N is an integer greater than two; the electrode layers are divided to be at least one first region and at least one second region which are opposite by at least one etched trench; along a stacking direction, the N electrode layers comprise an odd number first electrode layer, an even number first electrode layer, an odd number second electrode layer and an even number second electrode layer;
an odd number first electrode layer etched trench is provided in the odd number first electrode layer, an even number first electrode layer etched trench is provided in the even number first electrode layer; a profile of the odd number first electrode layer etched trench and a profile of the even number first electrode layer etched trench do not intersect along the stacking direction;
an odd number second electrode layer etched trench is provided in the odd number second electrode layer, an even number second electrode layer etched trench is provided in the even number second electrode layer; a profile of the odd number second electrode layer etched trench and a profile of the even number second electrode layer etched trench do not intersect; and
at least one dielectric layer, located in between adjacent electrode layers for provided dielectrics for insulation.

2. The multi-layer electrode connection structure according to claim 1, wherein a number of the electrode layers is M, M is greater than or equal to N; where M equals N, the profiles of the etched trenches in the N layers of the electrode layers are not intersecting along the stacking direction.

3. The multi-layer electrode connection structure according to claim 1, wherein where M is greater than N, the profiles of the etched trenches in the N layers of the electrode layers and the profiles of the etched trenches of the electrode layers more than N layers intersect in part.

4. The multi-layer electrode connection structure according to claim 1, wherein the electrode layers has at least one first edge and at least one second edge which are opposite, the etched trenches in the adjacent electrode layers are respectively close to the at least one first edge and the at least one second edge so to have the at least one first region and the at least one second region in the adjacent electrode layers stacked alternately.

5. The multi-layer electrode connection structure according to claim 1, wherein at least one trench is provided in the substrate; and a width of the at least one trench is greater than a width of the etched trenches.

6. The multi-layer electrode connection structure according to claim 1, wherein the at least one trench is distributed on a surface of the substrate in a similar patterned array; and a shape of the at least one trench comprises any of strips, rectangle and circle.

7. An on-chip capacitor, comprising: the multi-layer electrode connection structure as set forth in claim 1, and
at least one first conductive end cap, for connecting the at least one first region in the electrode layers; and
at least one second conductive end cap, for connecting the at least one second region in the electrode layers; and the at least one first conductive end cap and the at least one second conductive end cap are isolated.

8. A multi-layer electrode connection method, for forming the multi-layer electrode connection structure as set forth in claim 1, wherein the method comprising:
S1, providing a substrate, forming electrode layers on a surface of the substrate;
S2, etching the electrode layer on a surface layer, and divide the electrode layer to be at least one first region and at least one second region by at least one etched trench;
S3, forming at least one dielectric layer on a surface of the electrode layer; forming another electrode layer on an upper surface of the at least one dielectric layer;
S4, repeating steps S2-S3, executing S2 again; wherein profiles of the etched trenches in adjacent electrode layers among the N layers of electrode layers are not intersecting along a stacking direction, and N is a positive integer greater than two.

9. The multi-layer electrode connection method according to claim 8, wherein the step S4 further comprises: cutting or grinding edges of stacked electrode layers so to expose the at least one first region and the at least one second region of the electrode layers.

10. The multi-layer electrode connection method according to claim 8, wherein the method further comprising S5, forming at least one first conductive end cap for connecting the at least one first region and forming at least one second conductive end cap for connecting the at least one second region.

11. The multi-layer electrode connection method according to claim 8, wherein the electrode layers and the at least one dielectric layer are formed by at least one of atomic layer deposition or chemical vapor deposition; wherein the at least one first conductive end cap and the at least one second conductive end cap are formed by electroplating.
